(19) United States
(12) Patent Application Publication
(10) Pub. No.: US 2026/0343756 A1
(43) Pub. Date: Oct. 29, 2026

(54) Computer Case with Fabric Panel

(71) Applicant: Shanghai TRYX Technology Co., Ltd, Shanghai (CN)

(72) Inventors: Silong LAN, Shanghai (CN); Chi LIU, Shanghai (CN); Xingzhe WANG, Shanghai (CN); Chih-Hsuan LIN, Shanghai (CN)

(21) Appl. No.: 19/435,181

(22) Filed: Dec. 29, 2025

(30) Foreign Application Priority Data
Apr. 28, 2025 (CN) 202520825269.7

(51) Int. Cl. H05K 5/02; H05K 5/03

(52) U.S. Cl. CPC H05K 5/0214; H05K 5/0221; H05K 5/03

(57) ABSTRACT

The present invention provides a computer case with a fabric panel. The computer case comprises a case shell with an opening, wherein the opening is arranged with a detachable fabric panel comprising a panel body and a fabric cover. An elastic band is provided at the edge of the fabric cover. Through the elastic band, a main body portion of the fabric cover covers an outer side of the panel body, and an edge of the fabric cover is automatically tightened on an inner side of the panel body. With the computer case having the fabric panel according to the present invention, users can quickly detach the fabric panel for cleaning or replacement without tools; it balances heat dissipation efficiency and appearance personalization; and it ensures the flatness and stability of the fabric panel after installation.

### CROSS REFERENCE OF RELATED APPLICATIONS

The present application claims the priority of the Chinese utility model patent application which application number is 202520825269.7 filed Apr. 28, 2025, and the contents of which are hereby incorporated into this application by reference.

### FIELD OF THE INVENTION

The present invention belongs to the technical field of computer cases, and specifically relates to a computer case with a fabric panel.

### BACKGROUND

A computer case is an important component of a computer, primarily used to place and fix various parts. The front panel of a computer case is typically integrally formed from hard materials such as metal, plastic, or glass, and is fixed by clips, screws, or magnetic attraction.

Such traditional designs have the following problems:

Inconvenient Cleaning: Hard panel surfaces easily accumulate dust or stains, requiring the entire panel to be disassembled for cleaning, which is cumbersome.

Single Function: The material and structure are fixed, unable to change the appearance style (such as fabric, leather, and other personalized materials) according to user needs.

Contradiction between Heat Dissipation and Dust Prevention: Some cases use fully enclosed front panels leading to low air intake efficiency, while perforated panels improve heat dissipation but are prone to dust accumulation and difficult to clean.

Based on the above problems, existing improvement solutions include: realizing panel replacement through modular design, but they rely on hard materials and have complex fixing structures requiring tool-assisted disassembly and assembly.

Therefore, there is an urgent need for a front panel solution that combines easy cleaning, customizability, and tool-free quick disassembly and assembly.

### SUMMARY OF THE INVENTION

Aiming at the deficiencies of the prior art, the present invention provides a computer case with a fabric panel.

To solve the above technical problems, the present invention provides a computer case with a fabric panel, characterized in that the computer case comprises a case shell having an opening, wherein the opening is arranged with a detachable fabric panel comprising a panel body and a fabric cover, an elastic band is provided at an edge of the fabric cover, and through the elastic band, a main body portion of the fabric cover covers an outer side of the panel body, and an edge of the fabric cover is automatically tightened on an inner side of the panel body.

Preferably, a connecting assembly is provided between the edge of the fabric cover and the inner side of the panel body.

Preferably, the connecting assembly comprises pins and loop fasteners cooperating with the pins, wherein the pins are provided on one of the edge of the fabric cover and the inner side of the panel body, and the loop fasteners are provided on the other of the edge of the fabric cover and the inner side of the panel body.

Preferably, the connecting assembly is a magnetic attraction assembly or a hook-and-loop fastener assembly.

Preferably, the fabric cover is a breathable fabric cover.

Preferably, the inner side of the panel body is installed on the case shell via a snap-fit assembly.

Preferably, the snap-fit assembly comprises a mushroom head and a clip matching the mushroom head, wherein the mushroom head is provided on the inner side of the panel body, and the clip is provided on the case shell.

Preferably, the snap-fit assembly comprises positioning pin provided on the inner side of the panel body.

Preferably, the panel body is a mesh panel body.

Preferably, the elastic band is provided along an entire periphery of the edge of the fabric cover.

With the computer case having the fabric panel according to the present invention, users can quickly detach the fabric panel for cleaning or replacement without tools; it balances heat dissipation efficiency and appearance personalization; and it ensures the flatness and stability of the fabric panel after installation.

### BRIEF DESCRIPTION OF THE DRAWINGS

FIG. 1 is a structural schematic diagram of the computer case with a fabric panel according to the present invention.

FIG. 2 is an exploded view of the fabric panel in the computer case according to the present invention.

FIG. 3 is an assembly diagram of the fabric panel in the computer case according to the present invention.

### DETAILED DESCRIPTION

In order to make the technical problems solved by the present invention clearer, the present invention is further described below in combination with embodiments and the accompanying drawings. The specific embodiments described herein are only used to explain the present invention and are not intended to limit it.

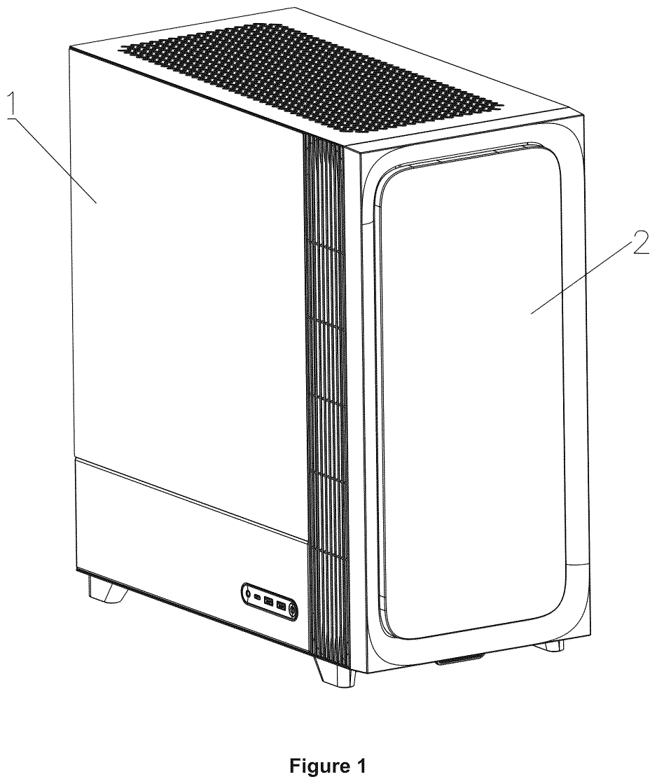

As shown in FIGS. 1 to 3, a specific embodiment of the computer case with a fabric panel according to the present invention is shown, which is particularly suitable for case scenarios requiring a balance of heat dissipation performance, aesthetics, and cleaning convenience. The computer case comprises a case shell 1 having an opening, wherein the opening is arranged with a detachable fabric panel 2.

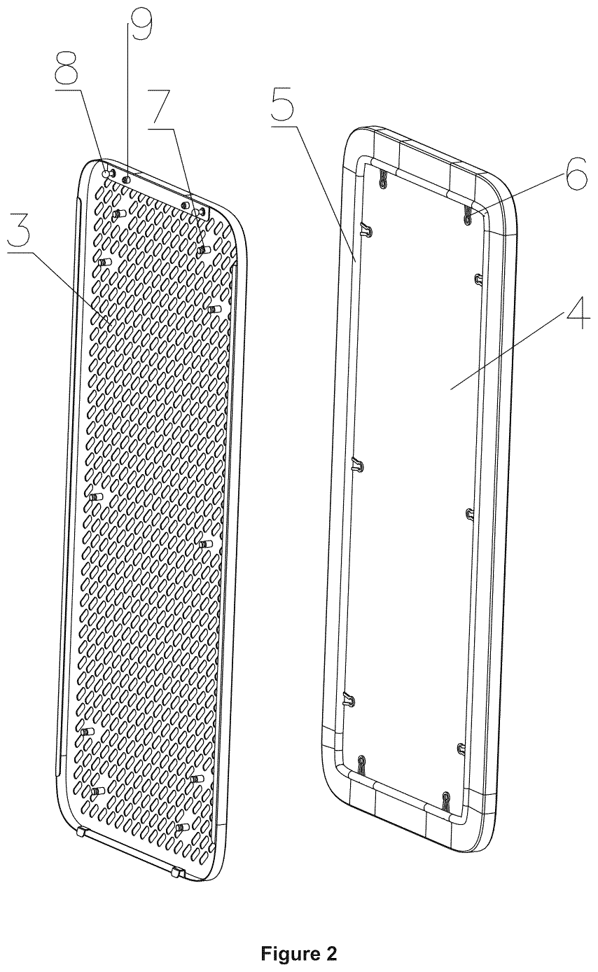

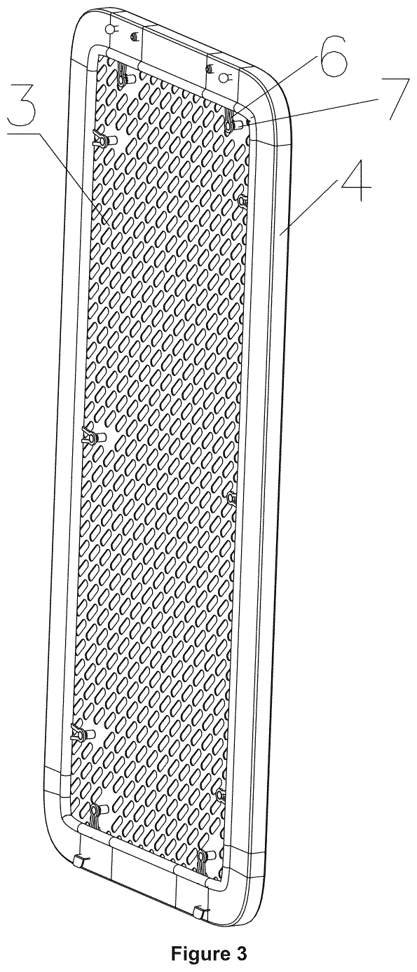

As shown in FIG. 2, the fabric panel 2 comprises a panel body 3 and a fabric cover 4. An elastic band 5 is provided at the edge of the fabric cover 4. As shown in FIG. 3, through the elastic band 5, a main body portion of the fabric cover 4 covers an outer side of the panel body 3, and an edge of the fabric cover 4 is automatically tightened on an inner side of the panel body 3, causing the main body portion of the fabric cover 4 to fit against the outer side surface of the panel body. The elastic band 5 can be continuously sewn along the edge of the fabric cover 4. The elastic band can use flexible elastic components such as rubber bands, elastic webbing, or elastic braided tape, maintaining tension stability through tensile deformation.

The fabric cover 4 can be a breathable fabric cover 4, for example, made of polyester blend or anti-static fiber material, with a hydrophobic coating applied to the surface to improve stain resistance. The panel body 3 is a mesh panel body, which can be made of metal material. The structure of the fabric cover and the mesh panel body can provide an air intake channel, optimize heat dissipation, and reduce direct dust inhalation while ensuring an opening rate of ≥50%, considering cost and durability. Furthermore, users can detach the fabric panel by hand within 30 seconds for washing and reuse, solving the problem of difficult dust accumulation cleaning associated with traditional hard panels.

The elastic band is provided along the entire periphery of the edge of the fabric cover. After being automatically tightened, the elastic band can sleeve around the periphery of the panel body, ensuring the flatness and stability of the fabric panel after assembly.

As shown in FIGS. 2 and 3, a connecting assembly facilitating detachable connection is provided between the edge of the fabric cover 4 and the inner side of the panel body 3 to secure the fabric cover. The easily detachable fabric cover allows for customized patterns or textures, enabling personalized expansion and supporting users to independently replace fabric panels of different materials/colors to meet home style matching requirements.

Specifically, the connecting assembly comprises a plurality of pins 7 and a plurality of loop fasteners 6 cooperating with the pins 7. The pins 7 are provided on the inner side of the panel body 3, and the loop fasteners 6 are correspondingly provided on the edge of the fabric cover 4. The pins can be double-headed studs. The positions of the pins and the loop fasteners can be swapped. The connecting assembly can also be replaced with other connection assemblies that facilitate disassembly, assembly, and connection, for example, a magnetic attraction assembly, including magnetic buttons and magnets, or a hook-and-loop fastener assembly, including hook tape and loop tape.

As shown in FIGS. 2 and 3, the inner side of the panel body 3 is installed on the case shell 1 via a snap-fit assembly.

Specifically, the snap-fit assembly comprises a mushroom heads 8 and a clip matching the mushroom head 8. The mushroom head 8 is provided on the inner side of the panel body 3, and the clip is provided on the case shell 1.

The snap-fit assembly comprises a positioning pin 9. The positioning pin 9 is provided on the inner side of the panel body 3 to further facilitate the installation of the fabric panel.

With the computer case having the fabric panel according to the present invention, users can quickly detach the fabric panel for cleaning or replacement without tools; it balances heat dissipation efficiency and appearance personalization; and it ensures the flatness and stability of the fabric panel after installation.

The foregoing describes specific embodiments of the present invention and does not constitute a limitation of the protection scope of the present invention. Any modifications and variations made based on the technical concept of the present invention shall be included within the protection scope of the present invention.

1. A computer case with a fabric panel, characterized in that the computer case comprising a case shell having an opening, wherein the opening is arranged with a detachable fabric panel comprising a panel body and a fabric cover, an elastic band is provided at an edge of the fabric cover, and through the elastic band, a main body portion of the fabric cover covers an outer side of the panel body, and an edge of the fabric cover is automatically tightened on an inner side of the panel body.

2. The computer case with a fabric panel according to claim 1, characterized in that a connecting assembly is provided between the edge of the fabric cover and the inner side of the panel body.

3. The computer case with a fabric panel according to claim 2, characterized in that the connecting assembly comprises a plurality of pins and a plurality of loop fasteners cooperating with the pins, wherein the pins are provided on one of the edge of the fabric cover and the inner side of the panel body, and the loop fasteners are provided on the other of the edge of the fabric cover and the inner side of the panel body.

4. The computer case with a fabric panel according to claim 2, characterized in that the connecting assembly is a magnetic attraction assembly or a hook-and-loop fastener assembly.

5. The computer case with a fabric panel according to claim 1, characterized in that the fabric cover is a breathable fabric cover.

6. The computer case with a fabric panel according to claim 1, characterized in that the inner side of the panel body is installed on the case shell via a snap-fit assembly.

7. The computer case with a fabric panel according to claim 6, characterized in that the snap-fit assembly comprises a mushroom head and a clip matching the mushroom head, wherein the mushroom head is provided on the inner side of the panel body, and the clip is provided on the case shell.

8. The computer case with a fabric panel according to claim 6, characterized in that the snap-fit assembly comprises positioning pin provided on the inner side of the panel body.

9. The computer case with a fabric panel according to claim 1, characterized in that the panel body is a mesh panel body.

10. The computer case with a fabric panel according to claim 1, characterized in that the elastic band is provided along an entire periphery of the edge of the fabric cover.
